(19) United States
(12) Patent Application Publication
(10) Pub. No.: US 2023/0420470 A1
(43) Pub. Date: Dec. 28, 2023

(54) WAVELENGTH-CONVERTING NEAR-INFRARED OPTICAL RECEIVER AND METHOD

(71) Applicant: KING ABDULLAH UNIVERSITY OF SCIENCE AND TECHNOLOGY, Thuwal (SA)

(72) Inventors: Boon Siew OOI, Thuwal (SA); Chun Hong KANG, Thuwal (SA); Tien Khee NG, Thuwal (SA); Omar ALKHAZRAGI, Thuwal (SA); Osman M. BAKR, Thuwal (SA)

(21) Appl. No.: 18/036,938

(22) PCT Filed: Nov. 15, 2021
(86) PCT No.: PCT/IB2021/060568

§ 371 Date: May 15, 2023

Related U.S. Application Data
(60) Provisional application No. 63/114,074, filed on Nov. 16, 2020.

(51) Int. Cl. H01L 27/146; G02B 6/42

(52) U.S. Cl. CPC H01L 27/14621; G02B 6/4215; G02B 6/4298; H01L 27/14625

(57) ABSTRACT

An optical converting receiver, for changing a visible light beam into a near-infrared, NIR, light beam, includes a substrate, a non-silicon-based optical element located on the substrate and configured to receive the visible light beam and convert the visible light beam into the NIR light beam, a silicon-based optical element located on the substrate and optically coupled to the non-silicon-based optical element, the silicon-based optical element being configured to propagate the NIR light beam, and a photodetector located on the substrate and optically coupled to the silicon-based optical element, the photodetector being configured to convert the NIR light beam into an electrical signal.

### CROSS-REFERENCE TO RELATED APPLICATIONS

This application claims priority to U.S. Provisional Patent Application No. 63/114,074, filed on Nov. 16, 2020, entitled “HYBRID WAVELENGTH-CONVERTING NEAR-INFRARED OPTICAL INTERCONNECTS FOR DISTRIBUTED OPTICAL-NODES,” the disclosure of which is incorporated herein by reference in its entirety.

### BACKGROUND

### Technical Field

Embodiments of the subject matter disclosed herein generally relate to a system and method for wavelength-converting quantum dots-based waveguiding photonics platform for downlink operation in visible light communication. More specifically, the embodiments discussed herein support detection of downlink data in visible light communication based on near-infrared quantum dots, hybrid integration with existing near-infrared photonics platforms and implements optical internet-of-things based on existing consumer electronics.

### Discussion of the Background

In the upcoming era of the Internet-of-Things (IoT), there is an ever-increasing demand more data, higher-speed transmission of the data, and more power efficient and secured data transmission, to support various application scenarios. With the increasing number of handheld devices, the conventional radio frequency (RF) communication channel is expected to saturate in the near future. In order to resolve the bandwidth crunching issue in the RF technology, the optical wireless communication (OWC) technologies, supplemented by the visible light communication (VLC), operating in the 400 to 680 nm range of the electromagnetic spectrum, has long been considered to resolve these challenges. The VLC or light-fidelity (Li-Fi) aim to address the overloading issue in the RF communication channels by utilizing the artificial indoor lighting as a hub for wireless data transmission points, in which it will create a bigger channel capacity in addition to the Wi-Fi technology.

Although VLC is a promising technology for future indoor communications, there is a number of challenges that remain unresolved in the existing VLC or optical-IoT systems. One of such challenges is that high-speed photodetectors have small areas due to resistance-capacitance (RC) limits and so can only collect a small portion of the flux of photons, reducing the received signal power. Using a focusing element resolves this issue, but limits the field of view, following the conservation of étendue, making the alignment requirements stricter. Thus, to reduce the chances of blocking of the optical signal, and to increase the amount of the received light, the receiver area should be of larger size, while, at the same time, not be limited by the RC limits. Such a design includes a flexible luminescent concentrator for free space optical communication by utilizing optical fiber doped with visible fluorescent dyes. Similarly, in other works, fluorescent optical concentrators were aimed to increase the detection efficiency for the incoming visible light signal, without degrading the field-of-view of the photodetectors. However, because these luminescent concentrators emit in the visible range, incorporating these materials into an indoor optical-IoT systems will create undesirable illumination to the human eye in a long run under an indoor environment.

Another challenge for the existing systems is that due to the higher absorption coefficient in the visible range, the existing silicon-based photodetectors are preferred as compared to the near-infrared (NIR) photodetectors, e.g., InGaAs or Ge-based photodetectors. A silicon-based photodetector or optical device is understood herein to be any device that includes silicon (Si) because it was the intent of the design of the device to include such material, and not because some Si impurities entered the device, unintentionally, during its manufacturing process. The NIR spectrum is defined herein to be between 700 nm and 2.0 μm. A narrower NIR spectrum is defined herein to be between 750 nm and 2.0 μm. Such inadequacy of the NIR photodetectors restricts the hybrid integration of the receiver module in VLC to existing photonics platforms designed based on the near-infrared wavelength region in smart devices.

In this regard, it is noted that the inventors have worked on a transmitter that is capable of using a visible light source for generating visible light and/or NIR based signals for optical communication with various devices in International Patent Application PCT/IB2021/056758, entitled “White-Light Illumination and Near-Infrared Communication System and Method Based on Multiple Pathway Visible-Light,” the entire content of which is incorporated herein by reference. This patent application explains how to generate NIR signals that are encoded with information and how to transmit them to various wireless devices within an enclosure, i.e., a chamber. However, how to record that information at a receiver still remains an issue.

Thus, there is a need to take advantage of the advantages of each of the technologies associated with the visible light and the NIR and provide a new system that can integrate both wavelength spectra.

### BRIEF SUMMARY OF THE INVENTION

According to an embodiment, there is an optical converting receiver for changing a visible light beam into a near-infrared, NIR, light beam. The optical converting receiver includes a substrate, a non-silicon-based optical element located on the substrate and configured to receive the visible light beam and convert the visible light beam into the NIR light beam, a silicon-based optical element located on the substrate and optically coupled to the non-silicon-based optical element, the silicon-based optical element being configured to propagate the NIR light beam, and a photodetector located on the substrate and optically coupled to the silicon-based optical element, the photodetector being configured to convert the NIR light beam into an electrical signal.

According to another embodiment, there is an optical-based communication system that includes a light source configured to generate visible light, a transmitter configured to receive the visible light and emit a mixture of a first visible light beam and a second visible light beam, wherein the first visible light beam is free of data and the second visible light beam is encoded to include data, an optical converting receiver configured to receive another visible light beam containing encoded data and convert the another visible light beam into a near-infrared, NIR, light beam, and a processor configured to encode the visible light and decode the NIR light beam.

According to still another embodiment, there is a visible light-based communication method that includes generating a visible light beam, encoding the visible light beam with data, emitting encoded visible light beam, receiving the encoded visible light beam at a polymer-based optical element, converting the encoded visible light beam into an encoded near-infrared, NIR, light beam with quantum dots located within the polymer-based optical element, transmitting the encoded NIR light beam to a photodetector to generate an electrical signal, and decoding the electrical signal with a processor to extract the encoded data.

### BRIEF DESCRIPTION OF THE DRAWINGS

For a more complete understanding of the present invention, reference is now made to the following descriptions taken in conjunction with the accompanying drawings, in which:

FIG. 1 is a schematic diagram of a visible light communication and illumination system that uses an optical converting receiver;

FIG. 2 illustrates an optical converting receiver that receives encoded visible light and transforms it into NIR light prior to decoding;

FIG. 3 shows a detailed view of the optical converting receiver when implemented as a fiber optic;

FIGS. 4A to 4C illustrate another implementation of the optical converting receiver that receives encoded visible light and transforms it into NIR light prior to decoding;

FIG. 5 illustrates yet another implementation of the optical converting receiver that receives encoded visible light and transforms it into NIR light prior to decoding;

FIG. 6 illustrates the absorbance and emission spectrum of the quantum dots used in the optical converting receiver for converting the visible light into the NIR light;

FIG. 7 illustrates the time-resolved photoluminescence measurement and single exponential decay fitting of the near-infrared quantum dots used in the optical converting receiver;

FIG. 8 illustrates one possible configuration for a data modulation test of the near-infrared quantum dots.

FIG. 9 illustrates the channel capacity and the allocated number of bits for each subcarrier as well as the received constellations for the optical converting receiver;

FIG. 10 illustrates the signal-to-noise ratio of each subcarrier and the power loading factor for the optical converting receiver;

FIG. 11 illustrates the bit error rate (BER) for each subcarrier of the for the optical converting receiver;

FIG. 12 illustrates a communication and illumination system that includes the optical converting receiver discussed above; and

FIG. 13 is a flow chart of a method that describes the optical communication performed by the optical converting receiver.

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to an optical receiver that is capable to receive encoded visible light and transform it into encoded NIR signals for later decoding. However, the embodiments to be discussed next are not limited to encoded signals or visible light to NIR, but may be applied to other light conversion applications.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, an optical converting receiver includes a non-silicon based optical element that is configured to receive visible light encoded signals and transform them into NIR encoded signals. The optical converting receiver further includes a silicon-based optical element, optically coupled to the non-silicon based optical element, and configured to transmit and/or amplify the NIR encoded signals. The optical converting receiver also includes a photodetector that is configured to record the NIR light encoded signals and transform them into electrical signals. Details of the optical converting receiver are discussed below with regard to the figures.

To transform the received visible light encoded signals into NIR encoded signals it is possible to use near-infrared quantum dots. The incorporation of near-infrared quantum dots that can convert from the visible range, i.e., light coming from a white light-emitting diode (LEDs) or laser or other artificial light source that can be encoded, to NIR encoded light can be implemented on the receiver or transceiver end, for the downlink operation, on various indoor smart devices, thus allowing remote access control over a vast variety of optical-IoT devices. Moreover, unlike the configuration adopted for the visible polymer-based waveguides having a higher attenuation loss (i.e., 100 dB/km), the NIR emitting color-converting element can be effectively coupled into matured silica-based optical waveguides that exhibit significantly lower losses (i.e., <1 dB/km) as compared to the visible range. This approach would open the way for integration of the novel optical converting receiver into existing photonic integrated circuits (PIC).

The silica-based optical fiber communication, operating in the NIR regime located at around 1300 nm and 1550 nm, is a relatively matured technology and had long been efficiently used for low attenuation, long-distance and high-speed data transmission after coupling with the erbium-doped fiber amplifier (EDFA) for signal amplification. Moreover, the InGaAs-based photodetectors (i.e., NIR photodetectors) with the detection range of 900 nm to 1700 nm are typically employed on the receiver end of the silica-based optical fiber communication for signal demodulation. Within the communication wavelengths of interest, the InGaAs-based photodetectors are known to have the highest responsivity and quantum efficiency as compared to other photodetectors, e.g., Si- and InGaN-based photodetectors.

In order to support the aforementioned data receiving capability for high-speed VLC system, quantum dots emitting in the near-infrared region, i.e., 700 or 750 nm to 2 or 2.5 μm region of the electromagnetic spectrum, and having short radiative recombination lifetime is thus described herein as the choice of wavelength-converting medium for optical-internet-of-things. This implementation differs from the other wavelength-converting mediums based on perovskite-based quantum dots emitting in the visible range [1, 2], as well as the integration of near-infrared quantum dots for near-infrared uplink operation (i.e., not for downlink operation) [3].

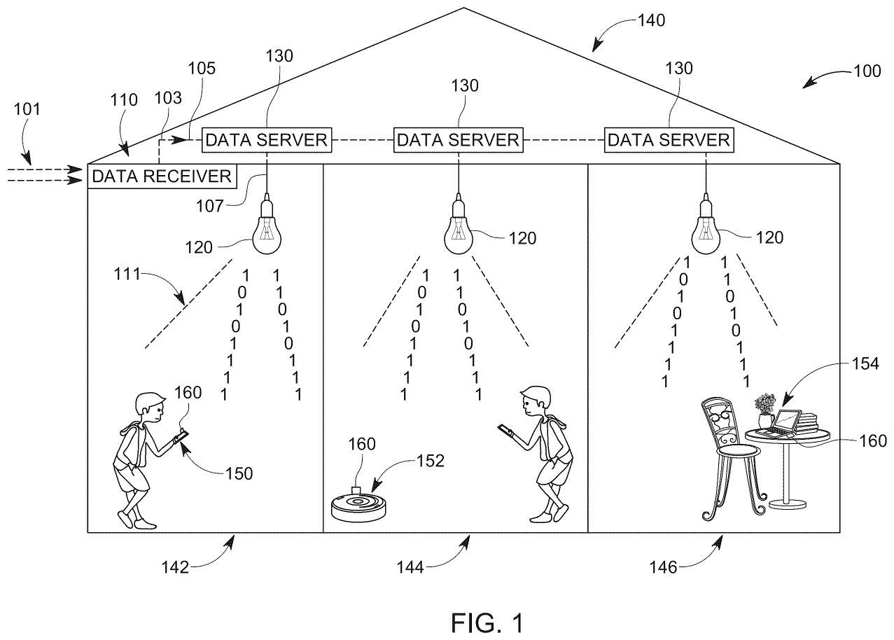

More specifically, as illustrated in FIG. 1, an indoor optical communication system 100 includes an optical data receiver 110, an optical data transmitter 120, and a data server 130. The optical data receiver 110 is configured to receive an optical visible signal 101 in the visible range and transform it into a NIR signal 103, which is transmitted along an optical waveguide 105 to the data server 130. The data server 130 is configured to perform one or more processing steps on the NIR signal 103, for example, to amplify it, to further encode it, to decode it, to add more information, to remove some of the already encoded information, etc. For example, if the incoming optical visible signal 101 carry Internet related data, the data server 130, which may be sitting in an office building 140, may be configured to add office specific information to an outgoing optical visible signal 111, which is emitted by the optical data transmitter 120. In one embodiment, the data server 130 may be configured to add different information to the incoming signal 101, based on the location of each smart device 150, 152, 154, etc. that receives such information. The location of each smart device may be associated with a room 142,144, or 146. While the example discussed in FIG. 1 relates to an office building, the same configuration may be implemented in a factory, where there are many different production sites, or a mall having plural shops, or a private residence, or any other possible building.

The data server 130 may be implemented as a single server for the entire building or as one data server for each room, as illustrated in FIG. 1. The data server 130 then sends commands 107 to the one or more optical data transmitters 120 for generating the corresponding optical visible encoded signal 111, which is again emitted in the visible spectrum. This means that the optical data transmitter 120, which may be a laser, LED device, any light source that can encode information into visible light, is used in the rooms 142 to 146 not only to illuminate them, as the generated light is visible, but also to simultaneously transmit/communicate data, which is embedded in the visible light.

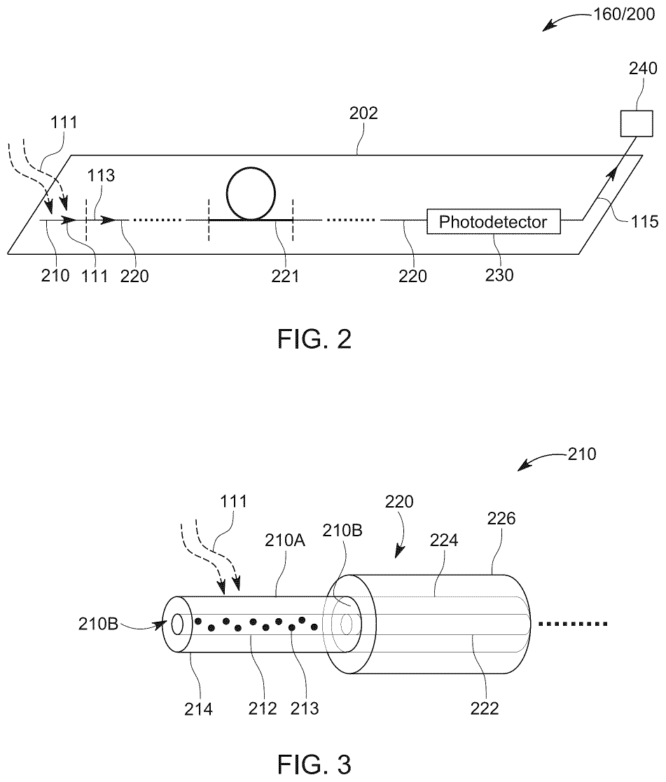

Each of the devices 150 to 154 includes an optical converting receiver 160 that may be similar or not to the data receiver 110. The optical converting receiver 160 may be configured to be implemented inside of or attached to the smart device that is being served by such receiver. In this regard, FIG. 2 shows a first possible implementation 200 of the optical converting receiver 160 and includes a substrate 202 on which are located a non-silicon-based optical element 210, a silicon-based optical element 220, and a photodetector 230. The optical converting receiver 200 may optionally include an erbium-doped fiber amplifier 221, sandwiched between two silicon-based optical elements 220. In this embodiment, the optical elements 210, 220 and 221 are implemented as optical fibers. A non-silicon optical element is defined herein as being a material or combination of materials that transmit an optical signal and none of the materials includes silicon atoms intentionally added during the manufacturing process or materials intentionally selected to include silicon atoms. In other words, a non-silicon optical element may include accidentally present silicon atoms, which were not added on purpose when the material was selected or manufactured. A silicon-based optical element includes at least one material that was selected on purpose to include an amount of silicon atoms, or the material was manufactured to include silicon atoms.

The structure and composition of the non-silicon and silicon based optical elements 210 and 220 is now discussed with regard to FIG. 3. The non-silicon optical element 210 includes a core 212 that is encapsulated by a cladding 214. The core 212 is made of a polymer-based medium, e.g., polymethyl methacrylate (PMMA), polydimethylsiloxane (PDMS), or any other solvent known in the art. Near-infrared quantum dots 213 are embedded into the core 212 and the NIR quantum dots 213 are selected to absorb the modulated incoming optical visible signals 111 of any wavelength, λ₁, that is shorter than the emission wavelength corresponding to the optical bandgap energy of the material forming the quantum dots. The NIR quantum dots 213 are also configured to re-emit a signal 113 (NIR light beam) at a longer wavelength, λ₂, while carrying and retaining the original information of the modulated optical signals. In one embodiment, lead sulphide (PbS)-based quantum dots (QDs) are used as the near-infrared conversion medium 213 for the visible light communication system. In this or another embodiment, the near-infrared quantum dots can absorb the incoming visible light (i.e., 380 nm to 700 or 750 nm) and re-emit in the near-infrared region (i.e., 750 nm to 2.0 or 2.5 μm). In one embodiment, the near-infrared quantum dots 213 can have a radiative recombination lifetime of 10 ps to 1 ms. In this or another embodiment, the near-infrared quantum dots can have a photoluminescence quantum yield (PLQY) of more than 50%.

The cladding 214 of the non-silicon optical element 210 may include any visible-transparent polymer as long as it has a lower refractive index than the core structure 212. It is noted that the incoming optical visible signal 111 is able to enter and pass the cladding 214 to arrive at the quantum dots 213. This is not the case for silicon-based optical element 220, where the cladding 224 may be made of an opaque material. FIG. 3 shows that the silicon-based optical element 220 also has a core 222 which is encapsulated by the cladding 224. A jacket 226 may be used to encapsulate the cladding 224. The core 222 of the silicon-based optical element 220 and the core 212 of the non-silicon optical element 210 are sized to have the same diameter so that they are optically coupled (for example, glued together or fused using heating method) to each other without losing any information at their interface. The cladding 224 and 214 may also be sized to have the same diameter as illustrated in FIG. 3. In one embodiment, the non-silicon-based optical element 210 has one or more sidewalls 210A and two end sides 210B, and the visible light beam 111 enters through the one or more sidewalls 210A of the non-silicon-based optical element 210 to reach the quantum dots 213.

The coupled light in the silicon-based optical element 220 can be integrated with the erbium-doped fiber amplifier 221 or any other amplifier known in the art for signal amplification and long-distance data transmission, before being demodulated by the photodetector 230, which is then converted into electrical signals 115. The system 200 may optionally include a processor 240 for processing the electrical signals 115. Although FIG. 2 shows the processor 240 being located away from the substrate 202, in one embodiment, the processor 240 may be directly attached to the substrate 202. While the system 200 shows a single non-silicon optical element 210, one skilled in the art would know that the system can be scaled up to arrays of quantum dots-embedded polymer fibers to enlarge the receiving area.

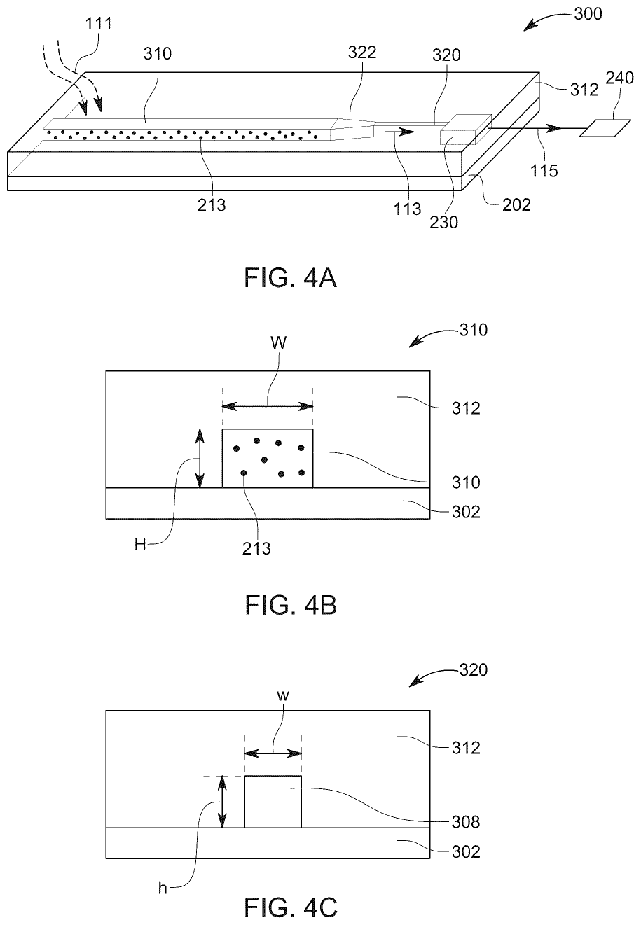

The optical converting receiver 160 may be implemented, in another embodiment as illustrated in FIGS. 4A to 4C, as a receiver 300 that includes a substrate 202 on which are placed a non-silicon-based optical element 310, a silicon-based optical element 320, a tapered coupler 322 that optically connects the non-silicon-based optical element 310 to the silicon-based optical element 320, and a photodetector 230. In this embodiment, the optical elements 310 and 320 may be implemented as optical waveguides. For this embodiment, the near-infrared quantum dots 213, which may be the same or different from the quantum dots of the embodiment of FIG. 2, are embedded in the polymer-based waveguide 310, which is tailored to absorb the incoming visible light beam 111 having a shorter wavelength, i.e., λ₁, than the optical bandgap energy of the quantum dots. The converted NIR light beam 113 can then be guided into the silica waveguide 320 through the tapered coupler 322, before being demodulated by a near-infrared waveguide photodetector 230. The receiver 300 is placed on top of a conventional silicon platform/substrate 202 and can be embedded in a visible-transparent polymer cladding 312. In one embodiment, both the polymer-based waveguide 310 and the silica-based waveguide 320 are covered by the same polymer cladding 312. In this or another embodiment, even the photodetector 230 is covered by the same polymer cladding 312. Note that in one embodiment, the polymer-based waveguide 310, the silica-based waveguide 320 and the photodetector 230 are directly coupled to each other. The tapered coupler 322 has a larger surface area facing the polymer-based waveguide than the area facing the silica-based waveguide.

In this embodiment, the near-infrared quantum-dots 213 can be embedded in the polymer-based waveguide 310 (e.g., PMMA, PDMS, etc.) or other solvent known to the art, having a larger width W and height H than the silica-based waveguide 320. As an example, the width W and height H of the quantum dots-embedded polymer core 310, a cross-section of which is shown in FIG. 4B, could be in the range of 1 mm to 1 μm, while the width w and height h of the silica-based waveguide 320, a cross-section of which is shown in FIG. 4C, could be in the range of 100 μm to 500 nm. In one application, the quantum dots-embedded polymer waveguide 310 has a refractive index larger than the substrate 202 and the polymer cladding 312. In this or another embodiment, the near-infrared quantum dots 213 can have a radiative recombination lifetime of 10 ps to 1 ms, and a photoluminescence quantum yield of more than 50%. Similar to the embodiment illustrated in FIG. 2, the incoming visible light beam 111 enters through the cladding 312 to reach the quantum dots 213. The waveguide 320 may have a core and a cladding, similar to optical element 220 and the cladding may not be transparent to the light beam 111, which is different from the cladding 312. In another embodiment, the cladding 312 is the only cladding provided around the core of the optical element 320.

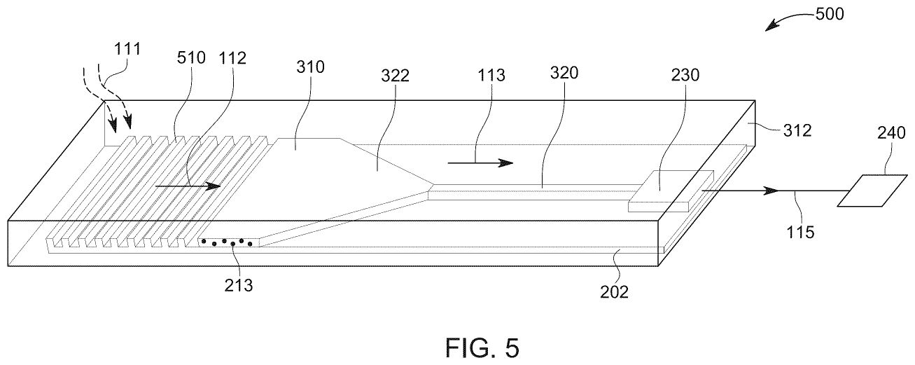

In yet another embodiment, as illustrated in FIG. 5, the optical converting receiver 160 may be implemented as a receiver 500 that includes a substrate 202 on which are placed a non-silicon-based optical element 310, a silicon-based optical element 320, a tapered coupler 322 that optically connects the non-silicon based optical element 310 to the silicon-based optical element 320, and a photodetector 230, which is optically coupled to the silicon-based optical element 320. In this embodiment, the optical elements 310 and 320 may be implemented as optical waveguides. For this embodiment, the near-infrared quantum dots 213, which may be the same or different from the quantum dots of the embodiment of FIGS. 2 and 4A, are embedded in the polymer-based waveguide 310, which, different from the embodiment illustrated in FIG. 4A, is not tailored to directly absorb the incoming visible light beam 111. In this embodiment, the incoming visible light beam 111 is configured to be first received by a diffraction-grating-based surface coupler 510 or another known diffraction-based coupling device. The diffraction-grating-based surface coupler 510 is formed on the same substrate as the polymer-based waveguide 310 and these two elements are optically connected, directly, to each other. The optical beam 112 generated by the diffraction-grating-based surface coupler 510, having a shorter wavelength, i.e., λ₁, than the optical bandgap energy of the quantum dots 213, is injected into the polymer-based waveguide 310 for being converted from the visible spectrum to the NIR spectrum. Note that the visible light beams 111 and 112 have the same spectral composition except that the diffraction-grating-based surface coupler 510 separates the beam 111 into its spectral components as the diffraction-grating-based surface coupler 510 is a diffraction grating. In other words, the light beam 112 is separated into individual light beams, each light beam having a different color. The quantum dots 213 transform the beam 112 into the NIR light beam 113, having a longer wavelength. The converted NIR light beam 113 can then be guided into the silica waveguide 320 through the tapered coupler 322, before being demodulated by a near-infrared waveguide photodetector 230.

The receiver 500 is placed on top of a conventional silicon platform/substrate 202 and can be embedded in a visible-transparent polymer cladding 312. In one embodiment, both the polymer-based waveguide 310 and the silica-based waveguide 320 are covered by the same polymer cladding 312. In this or another embodiment, even the photodetector 230 is covered by the same polymer cladding 312. Note that in one embodiment, the polymer-based waveguide 310, the silica-based waveguide 320 and the photodetector 230 are directly coupled to each other. The tapered coupler 322 has a larger surface area facing the polymer-based waveguide than the area facing the silica-based waveguide.

In this embodiment, the near-infrared quantum-dots 213 can be embedded in the polymer-based waveguide 310 (e.g., PMMA, PDMS, etc.) or other solvent known to the art. In one application, the quantum dots-embedded polymer waveguide 310 has a refractive index larger than the substrate 202 and the polymer cladding 312. In this or another embodiment, the near-infrared quantum dots 213 can have a radiative recombination lifetime of 10 ps to 1 ms, and a photoluminescence quantum yield of more than 50%.

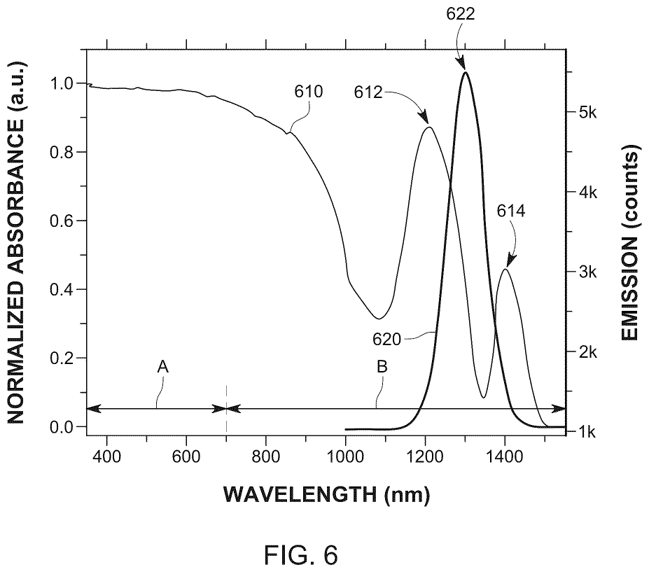

In one embodiment, the inventors have used lead sulphide (PbS)-based quantum dots (QDs) as the near-infrared conversion medium 213 for the visible light communication systems 200, 300 and 500 discussed above. In this embodiment, the synthesized PbS QDs powder was dispersed in octane and the QDs-octane solution was then sealed in a quartz cuvette. As shown in FIG. 6, the obtained absorbance spectrum 610 demonstrated high absorption towards the visible wavelength region A, thus elucidating its potential for broadband yet efficient photoconversion from a shorter wavelength to a longer wavelength in the NIR region B, which matches the responsivity of the intended InGaAs photodetectors 230. The emission spectrum 620 shows an emission peak 622 of the system to be located at 1300 nm based on the optical excitation at 920 nm. In addition, a sharp absorption peak 612 located at 1200 nm is originated from the PbS QDs, while another absorption peak 614 at 1400 nm is attributed to the OA ligands on the surfaces of PbS QDs, which are used to protect the PbS QDs from degradation and aggregation.

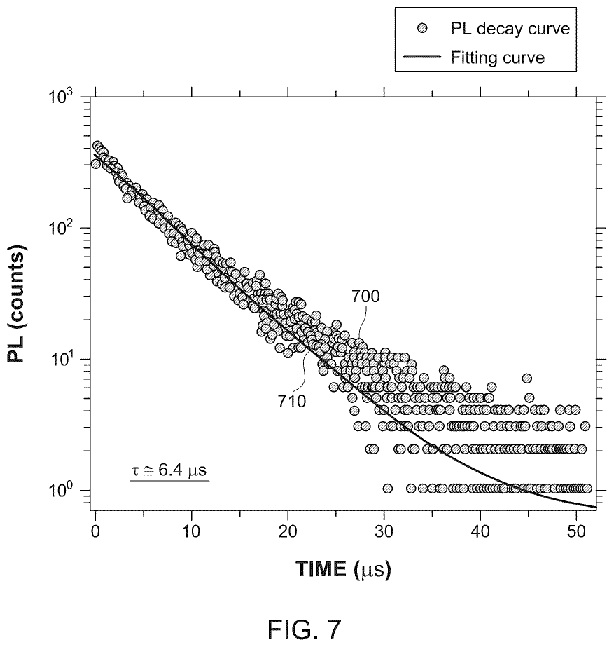

The PLQY of the sample used in one embodiment was measured to be about 88%. The steady state PL and PLQY measurements were performed with a fluorescence spectrometer. The absorption (A) spectrum was calculated by measuring the spectral transmittance (T) and reflectance (R) on the UV-VIS spectrometer and applying power continuity equation, i.e., A=1-T-R. The decay time was determined by the time-correlated single-photon counting (TCSPC) technique using a spectrofluorometer with a 669-nm laser pulse. As shown in FIG. 7, the measured TRPL signal 700 is then fitted with a single exponential decay function 710 with an estimated time constant (T) of about 6.4 ps.

In an effort to design an efficient VLC transceiver based on visible-to-NIR color-conversion that will broaden the detection spectrum of commercial InGaAs photodetectors, as well as for supporting the dual-functionalities of downlink and uplink operation, the embodiments discussed herein aimed to utilize high-quantum-efficiency colloidal quantum dots (QDs), emitting in the near-infrared region, as the intermediate color-conversion medium in the communication links. The rapid advancements in nano-scale materials having low dimensional structures, e.g., quantum wells (QWs), nanowires (NWs), and QDs, have enabled a number of potential applications in the current market. Among all, the colloidal QDs are the most attractive due to the facile solution-based synthesis method and enhanced stability based on surface passivation. Taking advantage of the stronger quantum confinement present in QDs, as compared to other low-dimensional structures, the development in this regard has enabled numerous applications in the field of optoelectronics, e.g., LEDs and photodetectors. The advantages of high quantum efficiency and short lifetime present in colloidal QDs could potentially open up a plethora of opportunities in the field of high-speed OWC systems, such as the phosphor-based transmitter and receiver module. In this regard, the colloidal lead sulphide (PbS) QDs, could be a promising candidate due to its broad absorption range from ultraviolet (UV) to NIR and possibility to control the emission wavelength in the NIR range simply by tuning the QDs diameters [4]. Moreover, the solution-processed QDs can be easily integrated as the color-converting components by facile and standard fabrication techniques, e.g., spin-coating, drop-coating, or fiber-pulling methods for emerging components required in high bit-rate communication channels, such as phosphor for microLEDs and luminescent fibers for photodetection.

The PbS QDs were synthesized using a conventional method as previously reported in [5]. The synthesis takes place in Ar gas by using the Schlenk line. For example, lead oxide (0.446 g), oleic acid (3.8 ml) and ODE (50 ml) are mixed in a three-neck flask. The method requires multiple vacuums to drain water and oxygen from the flask. The reaction temperature rises to 150° to form a pale-yellow lead oleate solution. Then the solution was pumped at 100° for 2 hours. The solution of 90 μL hexamethyldisilane ((TMS)2S) in 3 mL ODE was injected rapidly, and the color turned dark in several seconds. The reaction would continue for 8 minutes, and two other solutions (25 μL (TMS)2S in 3 mL ODE for each) were injected every 8 minutes. The reaction was quenched by an ice-bath and hexane. Acetone is added to precipitate the QDs.

The PbS QDs-octane solution was then sealed in a quartz cuvette to protect the sample from oxidation. FIGS. 6 and 7 shows the absorbance/emission spectra and the TRPL of the PbS QDs-octane solution. The HRTEM image (not shown) shows a well distributed size of the PbS QDs. The particle sizes (diameter) show a Gaussian distribution exhibiting a good quality of synthesized PbS QDs with an average size of 5.11 nm. Then, the QDs are deposited on a silicon wafer for composition analysis based on XPS and XRD. The XPS results show a large amount of OA ligands on the PbS QD surface, which contribute to the high O and C signals. Pb and S are also detected with an atomic ratio of 1.25:1. It is noted that the overdosed Pb precursor during the fabrication process constitute the Pb-rich PbS QDs with Pb ion filling the outer surface. On the other hand, the existence of the (111) surface allows the PbS QDs to be mostly Pb-rich regardless of the sizes. PbS QDs with this structure could provide more possible attachment points for OA ligands, which could increase the stability of PbS QDs. Moreover, the XRD analysis shows three different crystal faces due to the different stacking direction of PbS QDs on the silicon wafer.

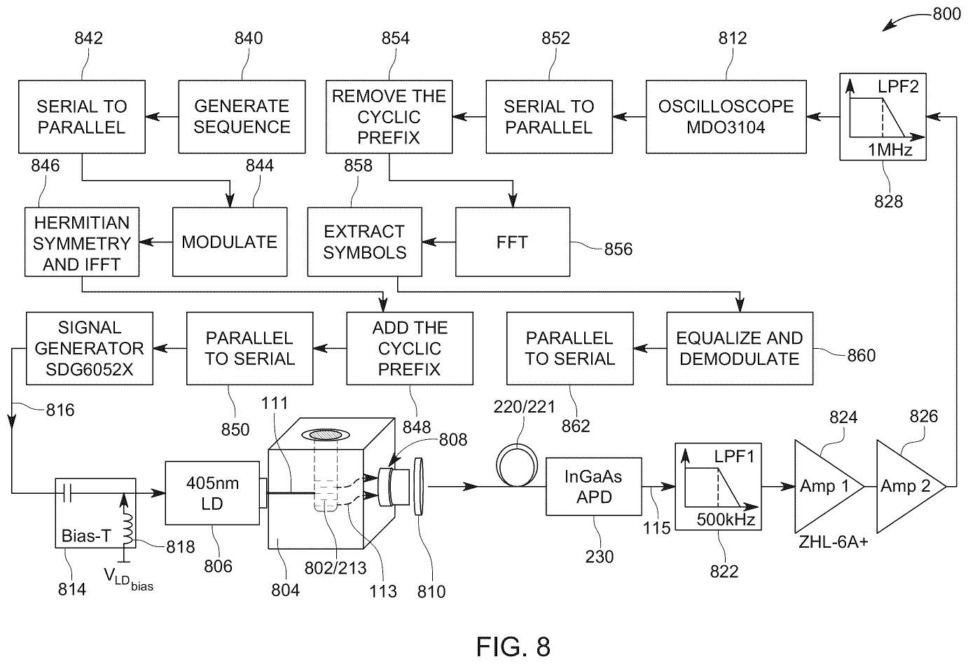

The as-synthesized PbS powder was re-dispersed in octane (10 mg/ml) under a nitrogen atmosphere. The sample was then placed in a quartz container. The PbS QDs-octane solution was then sealed with a rubber stopper and parafilm to protect the sample from oxidation. The prepared sample 802/213 was inserted into an integrating sphere 804 and a 405-nm laser diode (LD) 806 was used to excite the sample, as illustrated in FIG. 8. To receive the re-emitted NIR light beam 113 from the PbS QDs 213, a fiber collimating lens 808 was mounted on the exit port of the integrating sphere 804. A 1000-nm long-pass filter 810 was also used to remove any unabsorbed or stray photons coming directly from the excitation source. The modulated laser beam 111 excites the PbS QDs-octane solution 802 placed inside the integrating sphere 804, which feeds the collected light 113 into a silica optical fiber 220/221 with a core diameter of 400 μm, through the long-pass optical filter 810. The fiber 220/221 is then directly attached to an InGaAs-based avalanche photodetector 230, where the detected signal is recorded using a mixed-domain oscilloscope 812, for offline processing in MATLAB. A bias-tee 814 is used to combine the modulation signal 816 with the direct-current (DC) bias 818 to drive the 405-nm LD 806. The modulation bandwidth of the system 800 shown in FIG. 8 was measured by testing the impulse response. Based on the measurement, a frequency range from 50 to 250 kHz was utilized. To extend the usable bandwidth, an external circuit is attached to the bias-tee to further reduce the lower cut-off frequency from 100 kHz to 10 kHz. The detailed color conversion and signal acquisition schemes based on the OFDM (orthogonal frequency-division multiplexing) modulation scheme are represented on the block diagrams in FIG. 8 and are now discussed in more detail.

The electrical current signal 115 collected from the InGaAs-based APD 230 is amplified internally by a low noise pre-amplifier, which is integrated into the APD block. The detector multiplication factor, M, was set to the maximum value (M=20) in order to maximize the power of the signal of interest. Due to the fact that the APD has a wide-bandwidth transfer characteristics with a −3-dB frequency at 400 MHz and the fact that the signal bandwidth is from 50 to 250 kHz, a passive RC low-pass filter 822 with a cutoff frequency at 500 kHz was applied in order to eliminate the effect of wide-band noise at the high-frequency band and to improve the sensitivity of the system. Although the signal incoming from the APD 230 is magnified by its multiplication factor, due to the high degree of optical losses and due to the losses brought by the RC low pass filter 822, it was found that the output signal power is low. Therefore, an additional two amplifying stages were employed to amplify the signal. The amplifiers 824 and 826 used in this system are internally stabilized and designed for high-frequency applications with a cutoff bandwidth at 500 MHz and with a gain of 24 dB. Furthermore, considering the fact that the most significant noise was originated from the amplifying stages, another RC-low pass filter 828 with a 1-MHz cutoff was added in order to limit the bandwidth of the amplifiers.

To improve the efficiency of the communication link, the inventors used OFDM with adaptive data loading, which includes bit- and power-loading. This is achieved by first sending a test OFDM signal based on 2-quadrature amplitude modulation (2-QAM) using the OFDM steps shown in FIG. 8. A pseudorandom binary sequence (PRBS) is generated in step 840 and is then converted from serial to parallel in step 842. After that, the 2-QAM modulation is carried out in step 844. To make sure the generated signal can be used in intensity modulation of the laser, Hermitian symmetry is imposed in step 846 to ensure that the output of the inverse fast Fourier transform (IFFT) in the same step is real-valued. In other words, the process can be described based on Equations (1) and (2) as shown below:

X₀(n)=X_{N}_{_{FFT}}_{/2}(n)=0, (1)

and

X_{N}_{_{FFT}}₋ₖ(n)=X*ₖ(n), (2)

where Xₖ(n) is the QAM symbol on the k^{th} subcarrier in the n^{th} OFDM symbol and N_{FFT}=1,024 is the size of the IFFT.

The low frequency subcarriers (50 subcarriers corresponding to around 49 kHz) are set to zero to avoid the baseline drift of electronic components. Following the IFFT, a cyclic prefix is added in step 848 after each OFDM symbol. The formed array of N_{S}=150 OFDM symbols is converted to a serial sequence in step 850 and is sent through the channel using the AWG with a sampling frequency, f_{AWG}, of 1 MSample/s. After the detector 230 receives the signal, it is recorded using the oscilloscope 812 with a sampling frequency of 5 MSample/s. The first step in the offline processing is to resample down, the recorded signal, to the sampling frequency of the AWG and synchronize the received signal using the known training symbols. The cyclic prefix is removed in step 854, after converting the serial sequence to parallel in step 852. After performing the FFT in step 856 and removing the Hermitian symmetry symbols in step 858, the symbols are post-equalized in step 860 using a single-tap equalizer, based on the training symbols (e.g., four symbols are used in this embodiment). The symbols are then demodulated, and the bits are converted to a serial sequence in step 862 for comparison and to calculate the bit error ratio (BER).

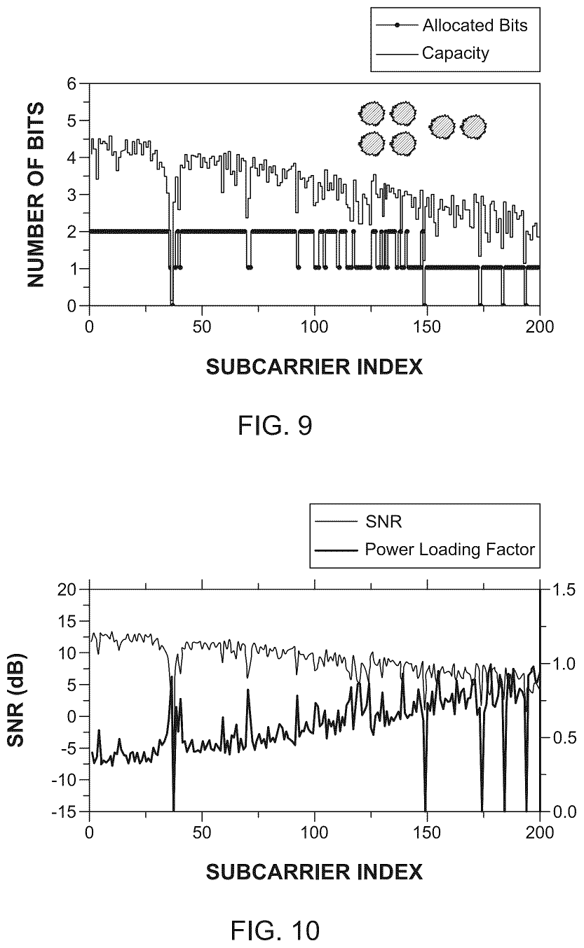

Based on the received 2-QAM test signal, the signal-to-noise ratio (SNR) is estimated based on the error vector magnitude (EVM). This is achieved by dividing the square of the magnitude of the transmitted position on the constellation map by the square of the magnitude of the difference vector between (1) the received position on the constellation map and (2) the transmitted position. After repeating this process for all symbols, the average SNR for each subcarrier is obtained. Based on the SNR, the number of bits allocated is determined and each subcarrier is given a factor to adjust its power to achieve the optimal performance. The number of bits depends on the channel capacity, as shown in FIG. 9, while FIG. 10 shows the power loading factors and the estimated SNR for each subcarrier. The channel capacity, C, can be estimated from the Shannon limit as shown in equation (3):

C=log₂(1+SNR). (3)

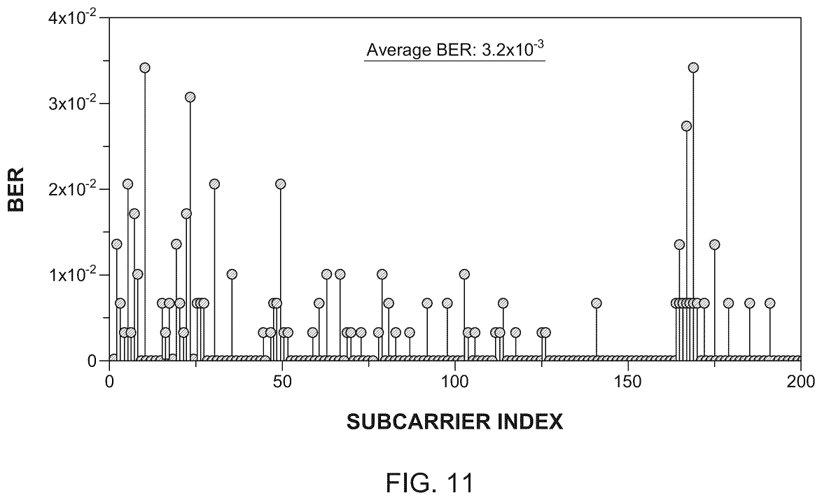

For subcarriers with SNRs below 3 dB, no bits are allocated. To calculate the overall data rate of the communication link, the inventors employed equation (4) as shown below:

$$Data Rate = \frac{{f}_{AWG}}{{N}_{FFT} + {N}_{CP}} {\sum }_{k = 1}^{{N}_{sc}} {log}_{2} ( {M}_{k} ) , \qquad ( 4 )$$

where N_{CP}=10 is the length of the cyclic prefix, N_{SC}=200 is the number of subcarriers used, Mₖ=2^{b} is the QAM order of the k^{th} subcarrier, and b is the number of bits allocated. Based on the bit loading scheme implemented, a data rate of 0.3 Mbit/s was achieved with an average BER of 3.2×10⁻³. This BER is below the forward error correction (FEC) BER limit of 3.8×10⁻³. FIG. 11 shows the BER for each subcarrier. Assuming a 7% FEC overhead, and accounting for the 2.67% training symbols used for post equalization and synchronization, the net data rate can be estimated to be around 0.27 Mbits/s.

The modulation bandwidth of the OFDM modulation was chosen as 50-250 kHz in order to comply with the frequency response of the communication link. The actual frequency response (not shown) of the setup shown in FIG. 8 was mainly limited by the color-conversion stage with a −3-dB upper limit at about 250 kHz and the lower limit at about 70 kHz. Thus, the higher band-limit bottleneck was identified to be due to the PL recombination lifetime of the QDs and possibly originated from the long-chain ligands used in this embodiment that created multiple trap states.

The above discussed embodiments have demonstrated a PbS QDs based system that uses the visible-to-near-infrared conversion material for a 0.27-Mbits/s OFDM-based optical communication link. The data rate in the range of Mbit/s is sufficient to enable non-destructive remote access control over a vast majority of optical-IoT devices in an indoor environment. Furthermore, the use of PbS QDs as the wavelength conversion medium could act as a broad spectrum VLC antenna that will extend the detection range of matured InGaAs-based photodetectors, as well as potentially serving as the dual-function of downlink and uplink transmissions for various optical-IoT systems. This also further paves the way to realize future solution-processed and flexible QDs-based components, e.g., luminescent fibers photoreceivers, which inherently exhibit large detection range covering from the visible-to-near-infrared region and without relying on cost-intensive epitaxial growth methods, as well as the further integration with efficient silica-based waveguides in photonic integrated circuits.

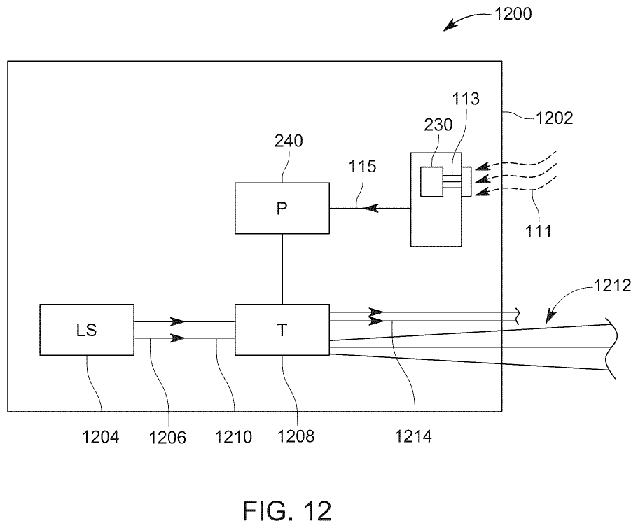

The various implementations of the optical converting receiver 200, 300, and 500 are now discussed with regard to an optical-based communication system 1200, which is illustrated in FIG. 12. The system 1200 may be a smart phone, tablet, laptop, robot, drone, or any other smart device. The system may include a common substrate 1202 on which is a light source LS 1204 is provided. The light source 1204 may be a laser device, an LED, etc., as long as the light source is capable to generate visible light 1206, e.g., white light. The system 1200 also includes a transmitter 1208 that is optically coupled to the light source 1204 and is configured to receive the visible light 1210. In one embodiment, the light source and the transmitter are coupled to each other through a waveguide 1210, for example, a fiber or an optical layer. The transmitter 1208 is configured to emit a mixture of a first visible light beam 1212, which is not encoded with data, and a second visible light beam 1214, which is modulated by a processor 240 to include the desired data. The first visible light beam 1212 is emitted outside the system 1200 to illuminate a given enclosure. The second visible light beam 1214 is also emitted outside the system 1200, to transmit the encoded data to another system. The mixture of the first and second visible light beam are not affecting the feel and vision of the persons being present inside the enclosure.

The system 1200 further includes an optical converting receiver 200, 300, or 500, as previously discussed, which is also located on the substrate 1202. The optical converting receiver is configured to receive another visible light beam 111 containing encoded data (which corresponds to the second visible light beam 1214, but transmitted from another system 1200), transform the visible light beam 111 into an NIR light beam 113, and record the NIR light beam at the photodetector 230. The generated electrical signal 115 is then provided to the processor 240, which may be located on the substrate 1202. The processor 240 may also be configured to decode the electrical signal 115.

While the system 1200 is configured to emit both white light for illumination and white light for data communication, in one embodiment, it is possible to adjust the system to not emit white light for illumination, especially if the system 1200 is a smart device that has limited power capabilities. In other words, with regard to FIG. 1, if the system 1200 is the data server 130, and has ample supplies of power, then the transmitter 1208 is configured to generate a first white light beam 1212 for illumination and a second white light beam 1214 for data communication. However, if the system 1200 is a smartphone, and the power supply is limited, the generation of the first white light beam 1212 may be suppressed.

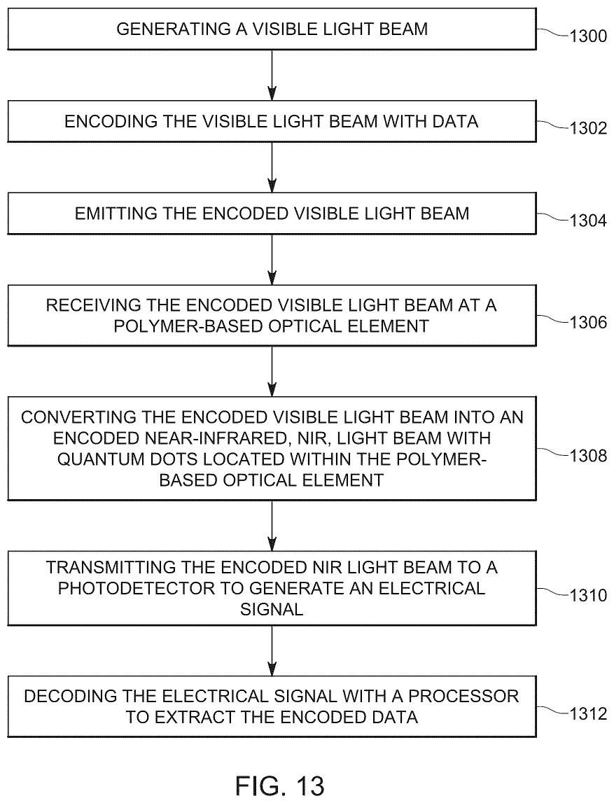

A method for using white and NIR light beams for data communication is now discussed with regard to FIG. 13. The method includes a step 1300 of generating a visible light beam 1206, a step 1302 of encoding the visible light beam 1206 with data, a step 1304 of emitting the encoded visible light beam 111, a step 1306 of receiving the encoded visible light beam 111 at a polymer-based optical element 210, 310, a step 1308 of converting the encoded visible light beam 111 into an encoded near-infrared, NIR, light beam 113 with quantum dots 213 located within the polymer-based optical element 210, 310, a step 1310 of transmitting the encoded NIR light beam 113 to a photodetector 230 to generate an electrical signal 115, and a step 1312 of decoding the electrical signal 115 with a processor to extract the encoded data.

The disclosed embodiments provide an optical converting receiver module with integrated near-infrared quantum dots for interconnection with existing silica-based photonics platform and high-speed optical data transmission. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

The entire content of all the publications listed herein is incorporated by reference in this patent application.
[1] Ibrahim Dursun, Chao Shen, Osman M. Bakr, Tien Khee Ng and Boon S. Ooi, “Multifunctional light, data device, or combination and systems,” U.S. Patent Publication No. US2019/0145587A1.
[2] Boon S. Ooi, Chun Hong Kang, Tien Khee Ng, Omar M. Bakr, Ibrahim Dursun, Lutfan Sinatra, and Marat Lutfullin, “Ultraviolet detection with high-speed wavelength-converting layer,” U.S. Provisional Patent Application No. 62/780,580.
[3] Boon S. Ooi, Chun Hong Kang, Omar Alkhazragi, and Tien Khee Ng, “Multiple pathway visible-light for white-light illumination and converted near-infrared optical uplink,” U.S. Provisional Patent Application No. 63/057,023, 2020.
[4] Choi, Y.; Sim, S.; Lim, S. C.; Lee, Y. H.; Choi, H. Ultrafast Biexciton Spectroscopy in Semiconductor Quantum Dots: Evidence for Early Emergence of Multiple-Exciton Generation. Sci. Rep. 2013, 3,1-6.
[5] Lee, J. W.; Kim, D. Y.; Baek, S.; Yu, H.; So, F. Inorganic UV-Visible-SWIR Broadband Photodetector Based on Monodisperse PbS Nanocrystals. Small 2016, 12 (10), 1328-1333

1. An optical converting receiver for changing a visible light beam into a near-infrared, NIR, light beam, the optical converting receiver comprising:
a substrate;
a non-silicon-based optical element located on the substrate and configured to receive the visible light beam and convert the visible light beam into the NIR light beam;
a silicon-based optical element located on the substrate and optically coupled to the non-silicon-based optical element, the silicon-based optical element being configured to propagate the NIR light beam; and
a photodetector located on the substrate and optically coupled to the silicon-based optical element, the photodetector being configured to convert the NIR light beam into an electrical signal.

2. The receiver of claim 1, wherein the non-silicon-based optical element includes (1) a transparent polymer and (2) quantum dots distributed within the transparent polymer and configured to change a first wavelength of the visible light beam to a second wavelength of the NIR light beam.

3. The receiver of claim 2, wherein the first wavelength is between 400 and 680 nm and the second wavelength is between 750 nm and 2.0 μm.

4. The receiver of claim 2, wherein the non-silicon-based optical element has one or more sidewalls and two end sides, and the visible light beam enters through the one or more sidewalls of the non-silicon-based optical element.

5. The receiver of claim 2, wherein the non-silicon-based optical element is a polymer-based optical fiber and the silicon-based optical element is a silica optical fiber.

6. The receiver of claim 2, wherein the quantum dots include lead sulphide

7. The receiver of claim 2, wherein the quantum dots have at least one of a photoluminescence quantum yield of more than 50% and a radiative recombination lifetime of 10 ps to 1 ms.

8. The receiver of claim 2, wherein the non-silicon-based optical element is a polymer-based waveguide, and the silicon-based optical element is a silica-based waveguide.

9. The receiver of claim 8, wherein the polymer-based waveguide has a cross-section area larger than a cross-section area of the silica-based waveguide.

10. The receiver of claim 9, further comprising:
an optical coupler optically coupling a first end of the polymer-based waveguide to a first end of the silica-based waveguide.

11. The receiver of claim 10, further comprising:
a diffraction-grating-based surface coupler attached to a second end of the polymer-based waveguide to direct the visible light beam to the first end of the polymer-based waveguide.

12. An optical-based communication system comprising:
a light source configured to generate visible light;
a transmitter configured to receive the visible light and emit a mixture of a first visible light beam and a second visible light beam, wherein the first visible light beam is free of data and the second visible light beam is encoded to include data;
an optical converting receiver configured to receive another visible light beam containing encoded data and convert the another visible light beam into a near-infrared, NIR, light beam; and
a processor configured to encode the visible light and decode the NIR light beam.

13. The system of claim 12, wherein the optical converting receiver comprises:
a substrate;
a non-silicon-based optical element located on the substrate and configured to receive the visible light beam and convert the visible light beam into the NIR light beam;
a silicon-based optical element located on the substrate and optically coupled to the non-silicon-based optical element, the silicon-based optical element being configured to propagate the NIR light beam; and
a photodetector located on the substrate and optically coupled to the silicon-based optical element, the photodetector being configured to convert the NIR light beam into an electrical signal.

14. The system of claim 13, wherein the non-silicon-based optical element includes (1) a transparent polymer and (2) quantum dots distributed within the transparent polymer and configured to change a first wavelength of the visible light beam to a second wavelength of the NIR light beam.

15. The system of claim 14, wherein the first wavelength is between 400 and 680 nm and the second wavelength is between 750 nm and 2.0 μm.

16. The system of claim 14, wherein the non-silicon-based optical element has one or more sidewalls and two end sides, and the visible light beam enters through the one or more sidewalls of the non-silicon-based optical element.

17. The system of claim 14, wherein the non-silicon-based optical element is a polymer-based optical fiber and the silicon-based optical element is a silica optical fiber.

18. The system of claim 14, wherein the non-silicon-based optical element is a polymer-based waveguide, and the silicon-based optical element is a silica-based waveguide.

19. The system of claim 18, further comprising:
an optical coupler optically coupling a first end of the polymer-based waveguide to a first end of the silica-based waveguide; and
a diffraction-grating-based surface coupler attached to a second end of the polymer-based waveguide to direct the visible light beam to the first end of the polymer-based waveguide.

20. The system of claim 14, wherein the quantum dots include lead sulphide.

21. The system of claim 14, wherein the quantum dots have at least one of a photoluminescence quantum yield of more than 50% and a radiative recombination lifetime of 10 ps to 1 ms.

22. A visible light-based communication method, the method comprising:
generating a visible light beam;
encoding the visible light beam with data;
emitting encoded visible light beam;
receiving the encoded visible light beam at a polymer-based optical element;
converting the encoded visible light beam into an encoded near-infrared, NIR, light beam with quantum dots located within the polymer-based optical element;
transmitting the encoded NIR light beam to a photodetector to generate an electrical signal; and
decoding the electrical signal with a processor to extract the encoded data.
